(19) United States
(12) Patent Application Publication
(10) Pub. No.: US 2014/0182632 A1
(43) Pub. Date: Jul. 3, 2014

(54) SUBSTRATE CLEANING APPARATUS AND SUBSTRATE CLEANING METHOD

(71) Applicant: EBARA CORPORATION, Tokyo (JP)

(72) Inventor: Tomoatsu ISHIBASHI, Tokyo (JP)

(21) Appl. No.: 14/139,626

(22) Filed: Dec. 23, 2013

(30) Foreign Application Priority Data
Dec. 28, 2012 (JP) 2012-287121

(51) Int. Cl. H01L 21/67; H01L 21/02

(52) U.S. Cl. CPC H01L 21/67023; H01L 21/02041
USPC 134/33; 134/103.2

(57) ABSTRACT

A substrate cleaning apparatus cleans a surface of a substrate such as a semiconductor wafer in a non-contact state by using two-fluid jet cleaning. The substrate cleaning apparatus includes a substrate holding mechanism configured to hold and rotate the substrate, with the front surface facing downward, in a horizontal state, and a two-fluid nozzle configured to jet a two-fluid jet flow, comprising a gas and a liquid, upwardly toward the front surface of the substrate held by the substrate holding mechanism.

### CROSS REFERENCE TO RELATED APPLICATION

This document claims priority to Japanese Patent Application No. 2012-287121 filed Dec. 28, 2012, the entire contents of which are hereby incorporated by reference.

### BACKGROUND OF THE INVENTION

1. Field of the Invention

The present invention relates to a substrate cleaning apparatus and a substrate cleaning method, and more particularly to a substrate cleaning apparatus and a substrate cleaning method for cleaning a surface (polished surface) of a substrate such as a semiconductor wafer in a non-contact state by using two-fluid jet cleaning. The substrate cleaning apparatus and the substrate cleaning method of the present invention can deal with a semiconductor wafer having a large diameter of 450 mm, and can be applied to a manufacturing process of a flat panel, a manufacturing process of an image sensor such as CMOS and CCD, a manufacturing process of a magnetic film for MRAM, and the like.

2. Description of the Related Art

As semiconductor devices are becoming finer these days, cleaning of various films, made of materials having different physical properties and formed on a substrate, is widely practiced. For example, in a damascene interconnect forming process for forming interconnects by filling a metal into interconnect trenches formed in an insulating film on the substrate surface, an extra metal on the substrate surface is polished away by chemical mechanical polishing (CMP) after the formation of damascene interconnects. A plurality of films such as a metal film, a barrier film and an insulating film, having different wettabilities with water, are exposed on the substrate surface after CMP.

Particles (defects) such as a residue of a slurry (slurry residue) that has been used in CMP, and metal polishing debris exist on the substrate surface having the exposed films, such as a metal film, a barrier film and an insulating film, by CMP. If cleaning of the substrate surface is insufficient and the residues remain on the substrate surface, the residues on the substrate surface may cause reliability problems such as the occurrence of leak from a residue portion, and poor adhesion. It is therefore necessary to clean the substrate surface, with high cleanliness, on which the plurality of films, such as a metal film, a barrier film and an insulating film, having different wettabilities with water are exposed.

As one of cleaning methods for cleaning a surface of a substrate such as a semiconductor wafer in a non-contact state, there has been known two-fluid jet cleaning which uses a two-fluid jet (2FJ), as disclosed in Japanese patent No. 3504023 and Japanese laid-open patent publication No. 2010-238850. The two-fluid jet cleaning is performed as follows: As shown in FIG. 1, a two-fluid nozzle 100 is arranged, with its front end facing downward, above a substrate W which is rotating horizontally with its front surface (polished surface) facing upward, and fine liquid droplets (mist) carried on a high-speed gas flow are jetted downwardly toward the surface of the substrate W from the two-fluid nozzle 100 to collide with the surface of the substrate W while the two-fluid nozzle 100 is moved in one direction parallel to the surface of the substrate W. Thus, particles 102 on the surface of the substrate W are removed (cleaned) by utilizing shock waves generated by the collision of the fine liquid droplets with the surface of the substrate W.

However, in the conventional two-fluid jet cleaning, particles remain on the surface of the substrate especially when the substrate has a surface having a hydrophobic property and such surface is cleaned, and thus it is difficult to clean the entire area of the surface of the substrate with high cleanliness. Specifically, as shown in FIG. 1, when the fine liquid droplets (mist) carried on the high-speed gas flow are jetted downwardly toward the surface of the substrate W from the two-fluid nozzle 100 to collide with the surface of the substrate W, the particles 102 which have been stirred up by the collision of the fine liquid droplets ride on a gas flow after the collision with the surface of the substrate W and float, and fly down on an area of the surface of the substrate W where the cleaning has been completed. Particularly, in the case of the hydrophobic surface, the particles 102 which have flown down on the cleaned area are liable to be stagnated thereon, and thus the particles 102 remain on the surface of the substrate W and become defects.

Further, a size of a silicon wafer is becoming larger from a maximum diameter of 300 mm to a maximum diameter of 450 mm, and thus it is expected to become more difficult to clean a substantially entire area of the surface of the substrate such as a silicon wafer having a diameter of 450 mm with high cleanliness.

### SUMMARY OF THE INVENTION

The present invention has been made in view of the above. It is therefore an object of the present invention to provide a substrate cleaning apparatus and a substrate cleaning method which can clean a surface of a substrate with high cleanliness by effectively utilizing inherent cleaning characteristics of a two-fluid jet cleaning.

According to one aspect of the present invention, there is provided a substrate cleaning apparatus for cleaning a substrate having a front surface and a reverse surface, the substrate cleaning apparatus comprising: a substrate holding mechanism configured to hold and rotate the substrate, with the front surface facing downward, in a horizontal state; and a two-fluid nozzle configured to jet a two-fluid jet flow, comprising a gas and a liquid, upwardly toward the front surface of the substrate held by the substrate holding mechanism.

According to the present invention, the upward two-fluid jet flow, jetted from the two-fluid nozzle, collides with the surface of the substrate which is horizontally rotating with its front surface facing downward, thereby cleaning the surface of the substrate. The particles which have been removed from the surface of the substrate at the time of the cleaning are moved downward by their own weights and a downward gas flow after the collision of the two-fluid jet flow with the surface of the substrate, thereby inhibiting reattachment of the particles onto the surface of the substrate. Thus, the two-liquid jet cleaning having its inherent cleaning characteristics can be performed.

In a preferred aspect of the present invention, the substrate cleaning apparatus further comprising: a moving mechanism comprising a rotatable support shaft vertically provided laterally of the substrate held by the substrate holding mechanism, and an oscillating arm having a base portion coupled to the support shaft and extending in a horizontal direction, the moving mechanism being configured to move the two-fluid nozzle in a direction parallel to the front surface of the substrate held by the substrate holding mechanism; wherein the two-fluid nozzle is attached to a distal end of the oscillating arm.

According to the present invention, the support shaft is rotated to drive the oscillating arm, thereby moving the two-fluid nozzle. Further, a moving velocity and a moving distance of the two-fluid nozzle can be controlled by controlling a rotational speed and a rotation angle of the support shaft.

In a preferred aspect of the present invention, the oscillating arm is configured to move the two-fluid nozzle in one direction from a cleaning start point spaced away from a center of the substrate, through a point just below the center of the substrate, to a cleaning finish point which is outside of the periphery of the substrate, while jetting the two-fluid jet flow from the two-fluid nozzle.

According to the present invention, the entire area of the surface of the substrate can be cleaned more uniformly.

In a preferred aspect of the present invention, the two-fluid nozzle comprises a slit-type nozzle having an elongated slit-shaped ejection port whose longitudinal length is equal to or longer than a radius of the substrate; and the ejection port is fixedly provided so as to extend in parallel to the surface of the substrate held by the substrate holding mechanism, and is arranged such that both a vertical line passing through the center of the substrate and a vertical line passing through a peripheral edge of the substrate pass through the ejection port.

According to the present invention, the entire area of the surface of the substrate can be cleaned more uniformly, in such a state that the two-fluid nozzle comprising the slit-type nozzle is fixed.

According to another aspect of the present invention, there is provided a substrate cleaning method for cleaning a substrate having a front surface and a reverse surface, the substrate cleaning method comprising: rotating the substrate, with the front surface facing downward, in a horizontal state; and jetting a two-fluid jet flow, comprising a gas and a liquid, upwardly toward the front surface of the substrate, which is rotating in a horizontal state, from a two-fluid nozzle.

In a preferred aspect of the present invention, the two-fluid nozzle is moved in one direction, parallel to the surface of the substrate, from a cleaning start point spaced away from a center of the substrate, through a point just below the center of the substrate, to a cleaning finish point which is outside of the periphery of the substrate, while jetting the two-fluid jet flow from the two-fluid nozzle.

According to the present invention, the upward two-fluid jet flow, jetted from the two-fluid nozzle, collides with the surface of the substrate which is horizontally rotating with its front surface facing downward, thereby cleaning the surface of the substrate. The particles which have been removed from the surface of the substrate at the time of the cleaning are moved downward by their own weights and a downward gas flow after the collision of the two-fluid jet flow with the surface of the substrate, thereby inhibiting reattachment of the particles onto the surface of the substrate. Thus, the surface of the substrate can be cleaned with high cleanliness by the two-liquid jet cleaning having its inherent cleaning characteristics.

### BRIEF DESCRIPTION OF THE DRAWINGS

FIG. 1 is a view for explanation of particle behavior in a conventional two-fluid jet cleaning;

FIG. 2 is a plan view showing an entire structure of a substrate processing apparatus incorporating a substrate cleaning apparatus according to an embodiment of the present invention;

FIG. 3 is a schematic perspective view showing the substrate cleaning apparatus, according to the embodiment of the present invention, which is used as a first cleaning unit shown in FIG. 2;

FIG. 4 is a view showing the relationship between a substrate held by a substrate holding mechanism of the first cleaning unit shown in FIG. 3, and a two-fluid nozzle;

FIG. 5 is a view for explanation of particle behavior in a two-fluid jet cleaning according to the embodiment of the present invention;

FIG. 6 is a view showing the relationship between a two-fluid nozzle used in another embodiment of the present invention, and the substrate held by the substrate holding mechanism;

FIG. 7 is a graph showing measured results in which the number of particles (defects) having a size of 100 nm or greater that has remained on a surface of the substrate was measured in Inventive Example 1, Comparative Example 1, and Before Cleaning, the graph being expressed in percentage (residual factor of defects) where the number of particles that has remained on the surface of the substrate in the case of Before Cleaning is assumed as a reference (100%), together with respective photographs in the cases of Inventive Example 1 and Comparative Example 1;

FIG. 8 is a graph showing measured results in which the number of slurries and the number of agglomerates of slurries, each having a size of 100 nm or greater, that have remained on the surface of the substrate were measured in Inventive Example 1, Inventive Example 2, Comparative Example 1, and Before Cleaning, the graph being shown in arbitrary unit in which the number of slurries that has remained on the surface of the substrate in the case of Before Cleaning is assumed as 1;

FIG. 9A is a view showing a state of the slurries which have remained on the surface of the substrate after cleaning; and

FIG. 9B is a view showing a state of the agglomerates of slurries which have remained on the surface of the substrate after cleaning.

### DETAILED DESCRIPTION

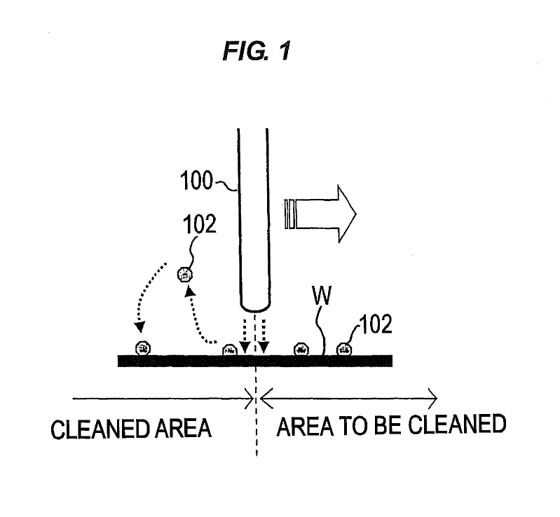

A substrate cleaning apparatus and a substrate cleaning method according to embodiments of the present invention will be described below with reference to FIGS. 1 through 9B.

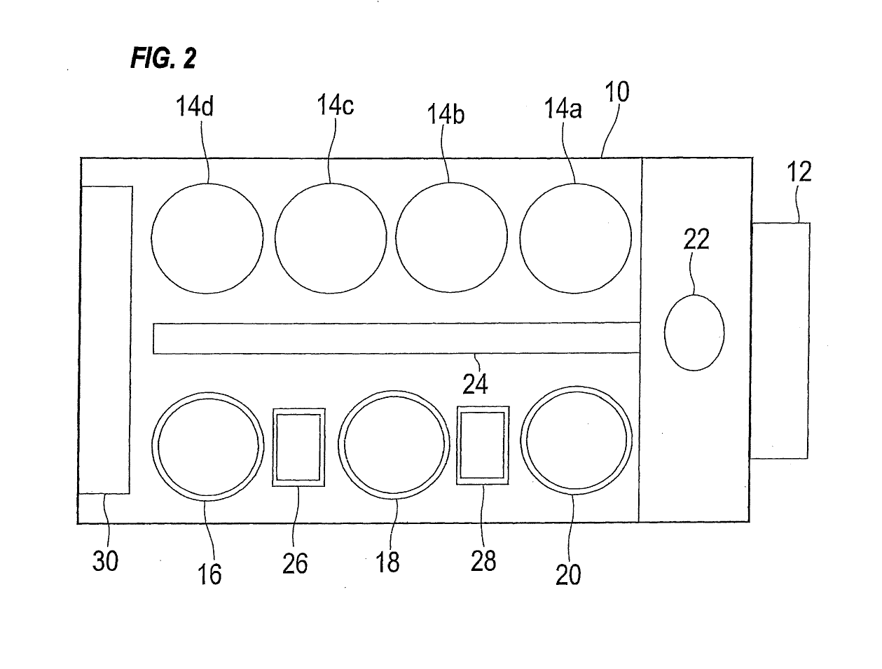

FIG. 2 is a plan view showing an entire structure of a substrate processing apparatus incorporating a substrate cleaning apparatus according to an embodiment of the present invention. As shown in FIG. 2, the substrate processing apparatus includes a generally-rectangular housing 10, and a loading port 12 for placing thereon a substrate cassette storing a large number of substrates, such as semiconductor wafers. The loading port 12 is disposed adjacent to the housing 10 and is capable of placing thereon an open cassette, a SMIF (standard manufacturing interface) pod or a FOUP (front opening unified pod). Each of the SMIF and the FOUP is a hermetically sealed container which houses therein a substrate cassette and is covered with a partition wall, and thus can keep independent internal environment isolated from an external space.

In the housing 10, there are provided a plurality of (four in this embodiment) polishing units 14a, 14b, 14c, 14d, a first cleaning unit 16 and a second cleaning unit 18 each for cleaning a substrate after polishing, and a drying unit 20 for drying a substrate after cleaning. The polishing units 14a, 14b, 14c, 14d are arranged in the longitudinal direction of the substrate processing apparatus, and the cleaning units 16, 18 and the drying unit 20 are also arranged in the longitudinal direction of the substrate processing apparatus. The substrate cleaning apparatus according to the embodiment of the present invention is applied to the first cleaning unit 16.

A first transfer robot 22 having an inverting mechanism for inverting the substrate by an angle of 180 degrees is disposed in an area surrounded by the loading port 12, and the polishing unit 14a and the drying unit 20 which are located near the loading port 12. A substrate transport unit 24 is disposed in parallel to the polishing units 14a, 14b, 14c, 14d. The first transfer robot 22 receives a substrate before polishing, with its front surface (surface to be polished) facing upward, from the loading port 12, and inverts the substrate by an angle of 180 degrees so that the front surface of the substrate faces downward. Then, the first transfer robot 22 transfers the substrate to the transport unit 24, receives a substrate after drying, with its front surface facing upward, from the drying unit 20, and returns the substrate to the loading port 12. The transport unit 24 transports a substrate transferred from the first transfer robot 22, transfers the substrate between the transport unit 24 and the polishing units 14a, 14b, 14c, 14d, and transfers the substrate transferred from the polishing units 14a, 14b, 14c, 14d to the first cleaning unit 16 with its front surface facing downward.

Between the first cleaning unit 16 and the second cleaning unit 18, there is provided a second transfer robot 26 for transferring a substrate between the first cleaning unit 16 and the second cleaning unit 18 and having an inverting mechanism for inverting the substrate by an angle of 180 degrees. Between the second cleaning unit 18 and the drying unit 20, there is provided a third transfer robot 28 for transferring a substrate between the second cleaning unit 18 and the drying unit 20. In the housing 10, there is provided a control panel 30 for controlling operations of respective devices in the substrate processing apparatus.

In this example, the substrate cleaning apparatus according to the embodiment of the present invention is used as the first cleaning unit 16. A roll cleaning unit in which elongated cylindrical roll cleaning members extending horizontally are brought into contact with the front surface and the reverse surface of the substrate in the presence of a cleaning liquid and the substrate and the roll cleaning members are being rotated in respective directions to scrub-clean the front surface and the reverse surface of the substrate, is used as the second cleaning unit 18. The second cleaning unit (roll cleaning unit) 18 is configured to use a megasonic cleaning in which an ultrasonic wave is applied at a frequency of several dozen Hz to about 1 MHz to the cleaning liquid to vibrate the cleaning liquid and to apply a force generated due to the vibrational acceleration of the cleaning liquid to fine particles deposited on the surfaces of the substrate, in combination with the scrub cleaning.

Further, a spin drying unit in which an IPA gas is ejected toward a substrate rotating horizontally from a moving injection nozzle to dry the substrate and the substrate is rotated at a high rotational speed to dry the substrate by a centrifugal force, is used as the drying unit 20.

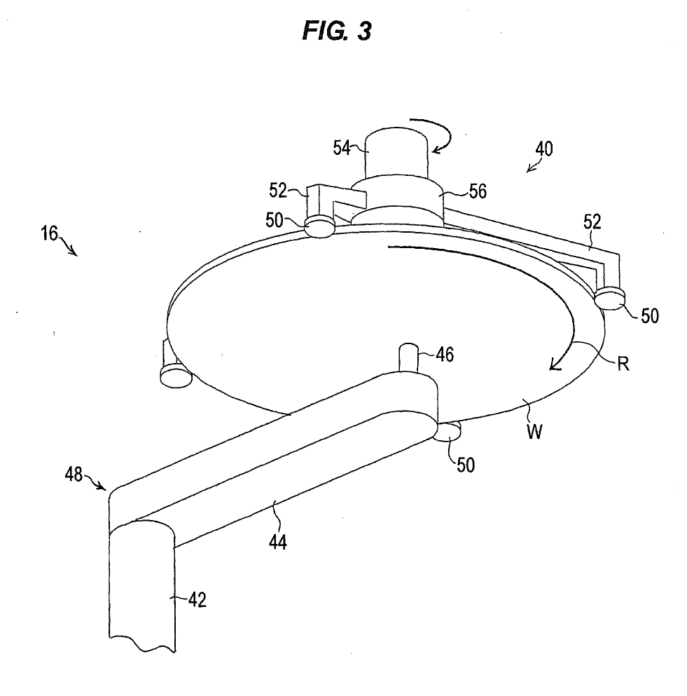

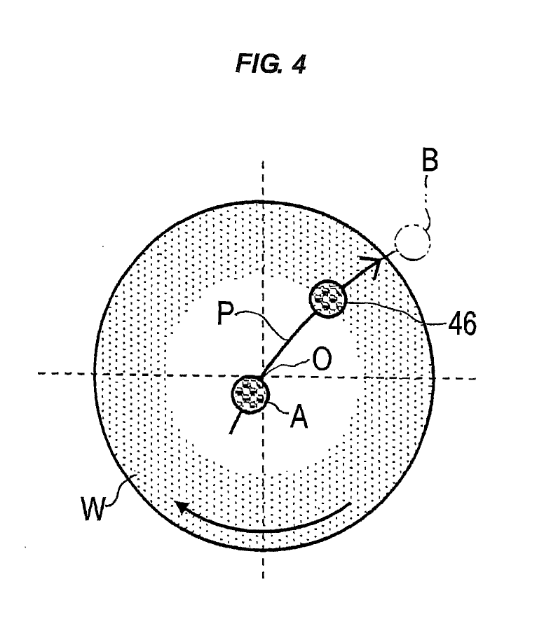

FIG. 3 is a schematic perspective view showing the substrate cleaning apparatus, according to an embodiment of the present invention, which is used as the first cleaning unit 16 shown in FIG. 2. FIG. 4 is a view showing the relationship between the substrate, held by a substrate holding mechanism in the first cleaning unit 16 shown in FIG. 3, and a two-fluid nozzle.

As shown in FIG. 3, the first cleaning unit 16, as the substrate cleaning apparatus according to the embodiment of the present invention, includes a substrate holding mechanism 40 for horizontally holding and rotating the substrate W, such as a semiconductor wafer, which has been polished by one of the polishing units 14a, 14b, 14c, 14d, with its front surface (polished surface) facing downward, a rotatable support shaft 42 vertically provided laterally of the substrate W held by the substrate holding mechanism 40, and an oscillating arm 44 having a base portion coupled to an upper end of the support shaft 42 and extending in a horizontal direction. The oscillating arm 44 is located below the substrate W held by the substrate holding mechanism 40. The support shaft 42 and the oscillating arm 44 constitute a moving mechanism 48, which allows a two-fluid nozzle 46 to move in a direction parallel to the surface of the substrate W held by the substrate holding mechanism 40.

A substantially cylindrical two-fluid nozzle 46 having a circular ejection port is vertically movably mounted on a free end (distal end) of the oscillating arm 44. A carrier gas supply line (not shown) for supplying a carrier gas comprising an inert gas such as N₂ gas and argon gas, and a cleaning liquid supply line (not shown) for supplying a cleaning liquid, such as pure water, water containing dissolved CO₂ gas, or hydrogen water are connected to the two-fluid nozzle 46. A two-fluid jet flow in which the cleaning liquid is contained in a state of fine liquid droplets (mist) in the carrier gas is created by jetting a mixture of the carrier gas, such as N₂ gas, and the cleaning liquid, such as pure water or water containing dissolved CO₂ gas, supplied into the two-fluid nozzle 46, at a high speed from the two-fluid nozzle 46. The two-fluid jet flow, created by the two-fluid nozzle 46, is jetted toward the surface of the rotating substrate W to collide with the surface of the substrate W, and thus particles and the like on the surface of the substrate can be removed (cleaned) by utilizing shock waves generated by the collision of the fine liquid droplets with the surface of the substrate.

The support shaft 42 is coupled to a motor (not shown), as a drive mechanism, for rotating the support shaft 42, thereby oscillating the oscillating arm 44 about the support shaft 42. A rotational speed and a rotation angle of the motor are controlled by signals from the control panel 30. Thus, an angular velocity and an oscillation angle of the oscillating arm 44 are controlled so that a moving velocity and a moving distance of the two-fluid nozzle 46 are controlled.

The substrate holding mechanism 40 has a plurality of (four as illustrated) arms 52 having respective distal ends on which chucks 50 are mounted to hold the substrate W in a horizontal state. A base end of each of the arms 52 is coupled to a base 56, which is rotatable together with a rotating shaft 54. With this configuration, the substrate W held by the chucks 50 of the substrate holding mechanism 40, with its front surface (polished surface) facing downward, is rotated in a direction shown by the arrow R.

FIG. 4 is a view showing a movement locus P, of two-fluid nozzle 46, depicted on the surface of the substrate. The ejection port of the two-fluid nozzle 46 moves on a plane parallel to the surface of the substrate in such a state that the ejection port is spaced downwardly from the surface of the substrate by a predetermined distance. As shown in FIG. 4, the two-fluid nozzle 46 is moved by the oscillation of the oscillating arm 44 in one direction so as to take an arc-shaped movement locus P, from a cleaning start point A, which is spaced away from the center O of the substrate W, through a point just below the center O of the substrate W, to a cleaning finish point B which is outside of the periphery of the substrate W, and thus the surface of the substrate W is cleaned. At the time of the cleaning, the two-fluid jet flow in which the cleaning liquid is contained in the state of fine liquid droplets (mist) in the carrier gas, is jetted upwardly from the ejection port of the two-fluid nozzle 46 toward the surface of the substrate W which is rotating horizontally.

An example of cleaning of the substrate in the first cleaning unit 16 will be described below. The substrate W is polished in one of the polishing units 14a, 14b, 14c, 14d with its front surface (surface to be polished) facing downward. Thus, the polished substrate W is transferred from the transport unit 24 to the first cleaning unit 16 in such a state that the front surface which has been polished in one of the polishing units 14a, 14b, 14c, 14d faces downward. The substrate holding mechanism 40 holds the substrate W horizontally by chucks 50 with the polished surface facing downward. After the substrate W is held horizontally by the substrate holding mechanism 40, the two-fluid nozzle 46 located at a stand-by position which is located laterally of the substrate holding mechanism 40 is moved to the cleaning start point A below the substrate W by driving the oscillating arm 44.

In this state, the substrate W is rotated horizontally, and the two-fluid jet flow in which the cleaning liquid is contained in the state of fine liquid droplets (mist) in the carrier gas, is jetted upwardly at a high speed from the two-fluid nozzle 46 toward the surface of the substrate W which is located above the two-fluid nozzle 46, thereby colliding the two-fluid jet flow with the surface of the substrate W. At the same time, the two-fluid nozzle 46 is moved at a predetermined moving speed in one direction so as to take the arc-shaped movement locus P from the cleaning start point A, through the point just below the center O of the substrate W, to the cleaning finish point B which is outside of the periphery of the substrate W. In this manner, particles and the like on the surface of the substrate W are removed (cleaned) with the shock waves generated by the collision of the fine liquid droplets with the surface of the substrate W.

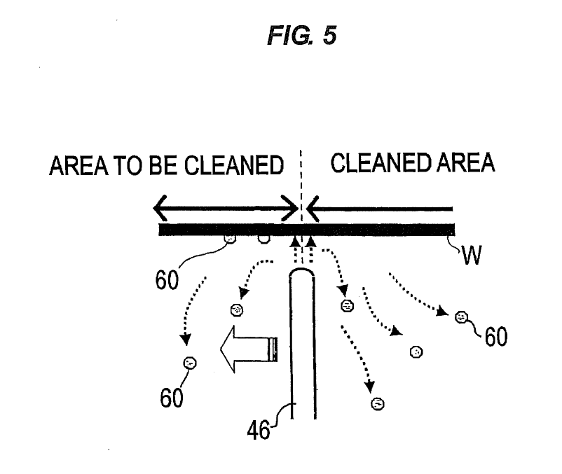

With this configuration, in this example, the two-fluid jet flow is jetted upwardly from the two-fluid nozzle 46 to collide with the surface of the horizontally rotating substrate W, with its front surface facing downward, while the two-fluid nozzle 46 is moved in one direction, and thus the entire surface of the substrate W can be cleaned. FIG. 5 shows particle behavior at the time of the cleaning.

As shown in FIG. 5, the particles 60 which have been removed from the surface of the substrate W at the time of the cleaning are moved downward by their own weights and a downward gas flow after the collision of the two-fluid jet flow with the surface of the substrate W, thereby inhibiting reattachment of the particles 60 onto the surface (the area to be cleaned and the cleaned area) of the substrate W. Therefore, the two-fluid jet cleaning can be performed while effectively utilizing the inherent cleaning characteristics of the two-fluid nozzle, without the necessity of considering the reattachment of the particles 60, which have been removed from the surface of the substrate W, onto the surface of the substrate W. Further, the entire area of the surface of the substrate W can be cleaned more uniformly, by cleaning the surface of the substrate W while moving the two-fluid nozzle 46 from the cleaning start point A, through the point just below the center O of the substrate W, to the cleaning finish point B which is outside of the periphery of the substrate W.

In the substrate processing apparatus shown in FIG. 2, the substrate, with its front surface (surface to be polished) facing upward, is taken out from a substrate cassette inside the loading port 12 and is then inverted by an angle of 180 degrees to allow the front surface to face downward. Thereafter, the substrate is transferred to one of the polishing units 14a, 14b, 14c, 14d where the surface of the substrate is polished by the specified polishing unit. Then, the polished substrate is transferred to the first cleaning unit 16 in such a state that the surface polished in one of the polishing units 14a, 14b, 14c, 14d faces downward, and the substrate is roughly cleaned in the first cleaning unit 16. Next, the roughly cleaned substrate is removed from the first cleaning unit 16 by the second transfer robot 26, and is then inverted by an angle of 180 degrees to allow the front surface to face upward. Thereafter, the substrate is finally cleaned in the second cleaning unit 18. Then, the cleaned substrate is removed from the second cleaning unit 18 and transferred to the drying unit 20 where the substrate is dried. Thereafter, the dried substrate is returned into the substrate cassette inside the loading port 12.

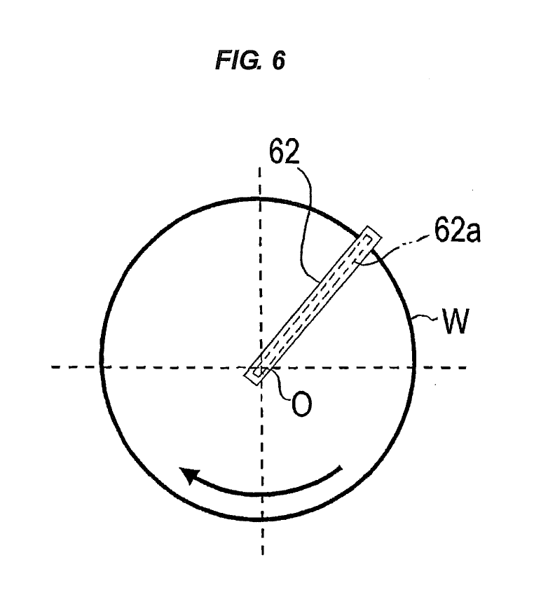

FIG. 6 is a view showing the relationship between a two-fluid nozzle 62 used in another embodiment of the present invention, and the substrate W held by the substrate holding mechanism. In this example, a slit-type nozzle having an elongated slit-shaped ejection port 62a is used as the two-fluid nozzle 62. The ejection port 62a extends in parallel to the surface of the substrate W held by the substrate holding mechanism, and is fixed at a position apart downwardly from the surface of the substrate by a predetermined distance. The ejection port 62a is arranged such that both a vertical line passing through the center of the substrate and a vertical line passing through the peripheral edge of the substrate pass through the ejection port. The ejection port 62a has an elongated and substantially rectangular shape having a small width, and the longitudinal length of the ejection port is equal to or longer than the radius of the substrate W. The ejection port 62a may have a longitudinal length equal to or longer than the diameter of the substrate W.

With this configuration, the entire surface of the substrate W can be cleaned more uniformly in a fixed state of the two-fluid nozzle 62, by using the two-fluid nozzle 62 comprising a slit-type nozzle having a slit-shaped ejection port 62a.

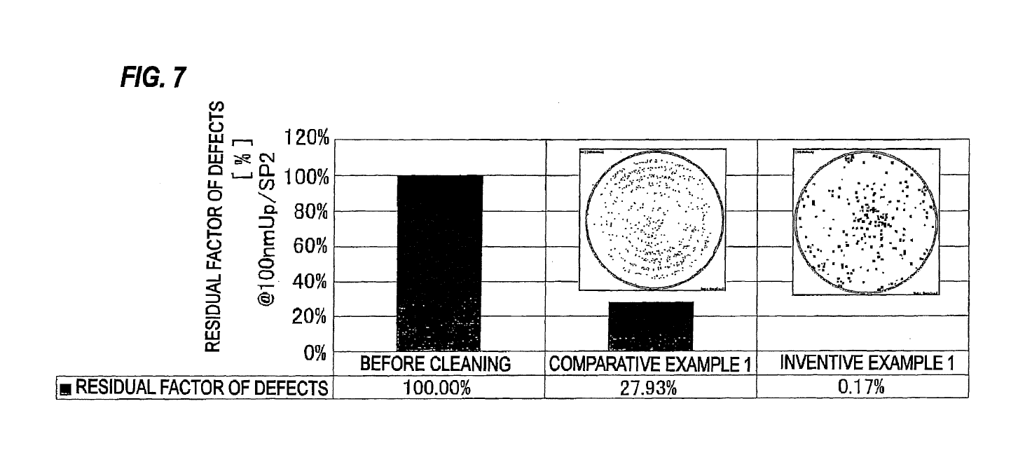

By using the substrate processing apparatus shown in FIG. 2, a surface of a TEOS blanket wafer (substrate) was polished by one of the polishing units 14a, 14b, 14c, 14d, and the polished surface of the substrate was cleaned using the first cleaning unit 16. After the cleaned substrate was spin-dried, the number of particles (defects) having a size of 100 nm or greater that remained on the surface of the substrate was measured. The measured result is shown together with a photograph of the substrate, as Inventive Example 1 in FIG. 7. For comparison, the polished substrate was spin-dried without cleaning after polishing, and the number of particles (defects) having a size of 100 nm or greater that remained on the surface of the substrate was measured. The measured result is shown as Before Cleaning in FIG. 7. A surface of a TEOS blanket wafer (substrate) was polished by one of the polishing units 14a, 14b, 14c, 14d, and the polished surface of the substrate was cleaned using a conventional two-fluid cleaning unit as shown in FIG. 1. The cleaned substrate was spin-dried, and the number of particles (defects) having a size of 100 nm or greater that remained on the surface of the substrate was measured. The measured result is shown together with a photograph of the substrate, as Comparative Example 1 in FIG. 7. In FIG. 7, a residual factor of defects is expressed in percentage where the number of particles (defects) that has remained on the surface of the substrate in the case of Before Cleaning is assumed as a reference (100%).

In Inventive Example 1, the substrate was cleaned by supplying a deionized water at a flow rate of 150 to 250 ml/min and N₂ gas at a flow rate of 50 to 150 SLM (standard litter/min) to the two-fluid nozzle 46 disposed at a location spaced from the substrate by the distance of 5 to 15 mm and having a nozzle diameter of 2 to 6 mm while the substrate was rotated at 100 min⁻¹ or lower. These conditions were applied to Comparative Example 1 as well.

As is clear from FIG. 7, it is understood that in Comparative Example 1 the residual factor of defects is approximately 28%, and the particles (defects) are liable to remain in a state distributed in a circular shape on the surface of the substrate. The state in which the defects remain in a state distributed in a circular shape on the surface of the substrate means a state in which the defects remain in the pattern of plural circles or in the pattern of a swirl on the surface of the substrate. In Inventive Example 1 the residual factor of defects is approximately 0.17%, and the number of the defects remaining on the surface of the substrate after the cleaning can be dramatically reduced as compared to Comparative Example 1.

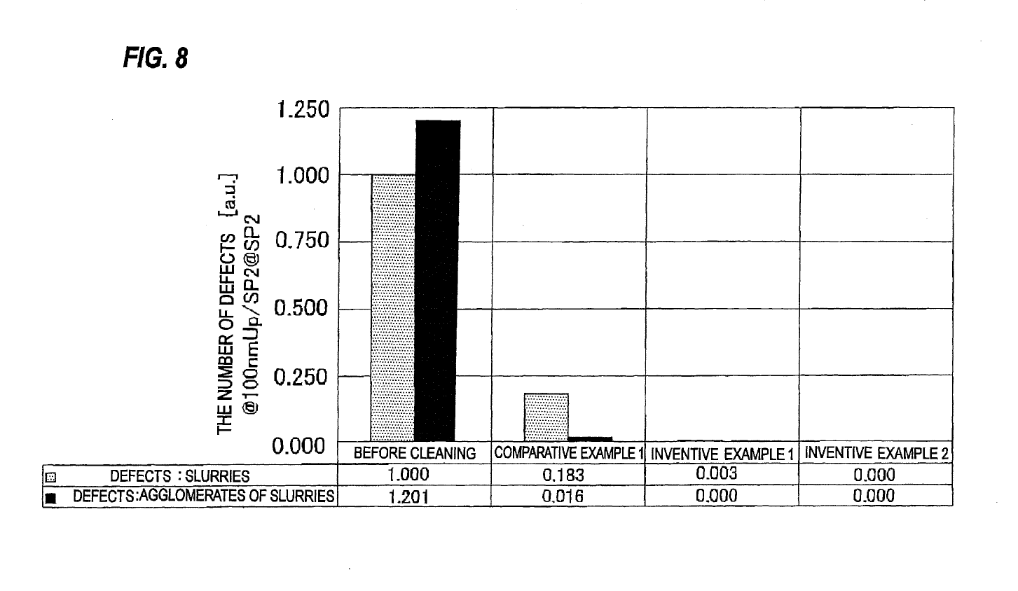

When a substrate was processed and spin-dried in the same condition as Inventive Example 1 shown in FIG. 7, the number of slurries and the number of agglomerates of slurries, each having a size of 100 nm or greater, that remained on the surface of the substrate were measured. The measured results are shown as Inventive Example 1 in FIG. 8. When a substrate was processed, except for spin-drying, in the same condition as Inventive Example 1, and then spin-dried at a rotational speed which is six times the rotational speed of Inventive Example 1. Then, the number of slurries and the number of agglomerates of slurries, each having a size of 100 nm or greater, that remained on the surface of the substrate were measured. The measured results are shown as Inventive Example 2 in FIG. 8. For comparison, the polished substrate was spin-dried without cleaning after polishing, and the number of slurries and the number of agglomerates of slurries that remained on the surface of the substrate were measured. The measured results are shown as Before Cleaning in FIG. 8. A substrate was cleaned in the same condition as Comparative Example 1 shown in FIG. 7 and spin-dried, and the number of slurries and the number of agglomerates of slurries were measured. The measured results are shown as Comparative Example 1 in FIG. 8. In FIG. 8, the number of slurries and the number of agglomerates of slurries are shown in arbitrary unit, in which the number of slurries that has remained on the surface of the substrate in the case of Before Cleaning is assumed as 1.

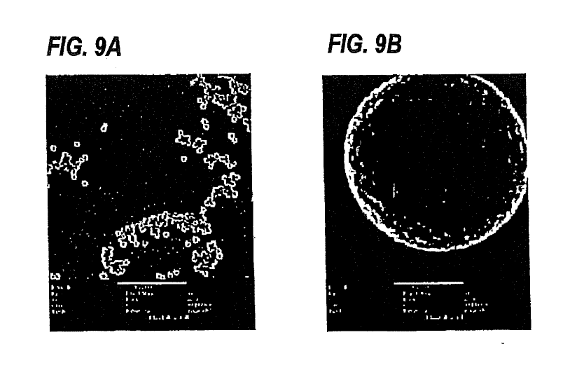

FIG. 9A is a view showing the state of the slurries which have remained on the surface of the substrate after cleaning, and FIG. 9B is a view showing the state of the agglomerates of slurries which have remained on the surface of the substrate after cleaning.

As is clear from FIG. 8, it is understood that the number of slurries and the number of agglomerates of slurries which remain on the surface of the substrate after cleaning, can be dramatically reduced in Inventive Examples 1 and 2 as compared to Comparative Example 1. Particularly, in Inventive Example 2, it is understood that both the number of slurries and the number of agglomerates of slurries can be reduced to zero.

Although certain preferred embodiments of the present invention have been shown and described in detail, it should be understood that various changes and modifications may be made without departing from the scope of the appended claims.

What is claimed is:

1. A substrate cleaning apparatus for cleaning a substrate having a front surface and a reverse surface, said substrate cleaning apparatus comprising:
a substrate holding mechanism configured to hold and rotate the substrate, with the front surface facing downward, in a horizontal state; and
a two-fluid nozzle configured to jet a two-fluid jet flow, comprising a gas and a liquid, upwardly toward the front surface of the substrate held by said substrate holding mechanism.

2. A substrate cleaning apparatus according to claim 1, further comprising:
a moving mechanism comprising a rotatable support shaft vertically provided laterally of the substrate held by said substrate holding mechanism, and an oscillating arm having a base portion coupled to said support shaft and extending in a horizontal direction, said moving mechanism being configured to move said two-fluid nozzle in a direction parallel to the front surface of the substrate held by said substrate holding mechanism;
wherein said two-fluid nozzle is attached to a distal end of said oscillating arm.

3. A substrate cleaning apparatus according to claim 2, wherein said oscillating arm is configured to move said two-fluid nozzle in one direction from a cleaning start point spaced away from a center of the substrate, through a point just below the center of the substrate, to a cleaning finish point which is outside of the periphery of the substrate, while jetting the two-fluid jet flow from said two-fluid nozzle.

4. A substrate cleaning apparatus according to claim 1, wherein said two-fluid nozzle comprises a slit-type nozzle having an elongated slit-shaped ejection port whose longitudinal length is equal to or longer than a radius of the substrate; and
said ejection port is fixedly provided so as to extend in parallel to the surface of the substrate held by said substrate holding mechanism, and is arranged such that both a vertical line passing through the center of the substrate and a vertical line passing through a peripheral edge of the substrate pass through said ejection port.

5. A substrate cleaning method for cleaning a substrate having a front surface and a reverse surface, said substrate cleaning method comprising:
rotating the substrate, with the front surface facing downward, in a horizontal state; and
jetting a two-fluid jet flow, comprising a gas and a liquid, upwardly toward the front surface of the substrate, which is rotating in a horizontal state, from a two-fluid nozzle.

6. A substrate cleaning method according to claim 5, wherein said two-fluid nozzle is moved in one direction, parallel to the surface of the substrate, from a cleaning start point spaced away from a center of the substrate, through a point just below the center of the substrate, to a cleaning finish point which is outside of the periphery of the substrate, while jetting said two-fluid jet flow from said two-fluid nozzle.
